(19) United States
(12) Patent Application Publication
(10) Pub. No.: US 2004/0183611 A1
(43) Pub. Date: Sep. 23, 2004

(54) Multi-band oscillator that can oscillate at each oscillation band under optimum oscillation conditions

(75) Inventors: Kimihiro Nakao, Fukushima-ken (JP); Takeo Suzuki, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/801,627

(22) Filed: Mar. 16, 2004

(30) Foreign Application Priority Data
Mar. 20, 2003 (JP) 2003-076940

(51) Int. Cl. H03K 3/26

(52) U.S. Cl. 331/179

(57) ABSTRACT

A multi-band oscillator includes plural pairs of oscillation transistors, which are differentially connected and which are provided independently for each oscillation frequency band; and feedback capacitor elements that connect the mutual collector and base of each pair of the oscillation transistors. The collectors of one of each pair of the oscillation transistors are connected to one another, and the collectors of the other pairs of the oscillation transistors are connected to each other. Between the collector of one of the oscillation transistors and the collector of the other oscillation transistor, a plurality of capacitor elements for switching the oscillation frequency band are connected via switching devices connected in series thereto in such a manner as to correspond to each pair of oscillation transistors, and only one pair of oscillation transistors corresponding to the capacitor element which is connected to the switching device which is turned on are placed in an operating condition.

### BACKGROUND OF THE INVENTION

1. Field of the Invention

The present invention relates to a multi-band oscillator for use in a transmitter-receiver, etc., for wireless LAN (Local Area Network).

2. Description of the Related Art

A conventional multi-band oscillator will now be described with reference to FIG. 2. The emitters of a first oscillation transistor 1 and a second oscillation transistor 2 are connected to a constant-current source 3, and a power-supply voltage is applied to the collectors thereof via resistors 4 and 4. Feedback circuits 5 are connected between the base of the first oscillation transistor 1 and the collector of the second oscillation transistor 2 and between the base of the second oscillation transistor 2 and the collector of the first oscillation transistor 1. The feedback circuit 5 is formed of a resistor 5a, a first feedback capacitor 5b, and a second feedback capacitor 5c, which are connected in series.

Then, a resonance circuit 6 is connected between a first terminal “a” and a second terminal “b”, which are connection points of the first feedback capacitor 5b and the second feedback capacitor 5c of the two corresponding feedback circuits 5.

The resonance circuit 6 includes a varactor diode 7 provided between the first terminal “a” and the second terminal “b”; a first inductor 8 connected between the first terminal “a” and the second terminal “b”; a second inductor 9 and a third inductor 10, which are connected in series between the first terminal “a” and the second terminal “b”; and a first switching diode 11a and a second switching diode 11b, which function as switching means 11 and which are connected between the second inductor 9 and the third inductor 10. The varactor diode 7 is connected in series to a DC blocking capacitor 12, and a correction capacitor 13 is connected in parallel to the varactor diode 7. Then, the anode of the varactor diode 7 is connected to a ground via a bias resistor 14, and a tuning voltage is supplied to the cathode thereof from a tuning terminal Vt via a power-feed resistor 15.

On the other hand, one end (cathode) of the first switching diode 11a and one end (cathode) of the second switching diode 11b are connected to each other, and the other ends are correspondingly connected to the second inductor 9 and the third inductor 10. One end of a bias resistor 16 is connected to the cathodes of the first switching diode 11a and the second switching diode 11b, and a fixed bias voltage from a bias terminal Bf is applied thereto via the bias resistor 16. Furthermore, one end of a power-feed resistor 17 is connected to the midpoint of the first inductor 8, and a switching voltage from a switching terminal Bs is supplied thereto via the power-feed resistor 17. In order that noise superposed on the fixed bias voltage and the switching voltage be cut off, the other end of the bias resistor 16 and the other end of the power-feed resistor 17 are connected to a ground via DC blocking capacitors 18 and 19, respectively. Furthermore, the other end of the power-feed resistor 17 is connected in DC to a ground via a bias resistor 20.

In the balanced oscillator of the above configuration, when the oscillator is made to oscillate at a high-frequency band, the first switching diode 11a and the second switching diode 11b are turned on, causing the second inductor 9 and the third inductor 10 to be connected in series and to be connected in parallel to the first inductor 8. Therefore, the inductance value of the whole is decreased to increase the resonance frequency of the resonance circuit 6. On the other hand, when the oscillator is made to oscillate at a low-frequency band, the first switching diode 11a and the second switching diode 11b are turned off, causing the second inductor 9 and the third inductor 10 to be disconnected from each other, so that the resonance frequency of the resonance circuit 6 is decreased.

For this reason, a fixed bias voltage from the bias terminal Bf is always applied to the cathodes of the first switching diode 11a and the second switching diode 11b, and the on/off state is switched in accordance with a switching voltage.

In the conventional multi-band oscillator, since the oscillator transistor is commonly used at various oscillating bands, the operation point (mainly the collector current) is fixed, and the optimum oscillation conditions cannot be set at each oscillation band. In a similar manner, since the feedback capacitance element is commonly used at various oscillation bands, the oscillation conditions at each oscillation band cannot be made optimum.

### SUMMARY OF THE INVENTION

An object of the present invention is to provide a multi-band oscillator that can oscillate at each oscillation band under optimum oscillation conditions.

To achieve the above-mentioned object, the present invention provides a multi-band oscillator including: a plurality of pairs of first and second oscillation transistors, which are differentially connected and which are provided independently for each oscillation frequency band; and a feedback capacitor element that connects the mutual collector and base of each of the pairs of oscillation transistors, wherein the collectors of the first oscillation transistors are connected to one another, the collectors of the second oscillation transistors are connected to one another, a plurality of capacitor elements for switching the oscillation frequency band in such a manner as to correspond to each of the pairs of the oscillation transistor are connected via switching means connected in series thereto between the collectors of the first oscillation transistors and the collectors of the second oscillation transistors, and only one pair of oscillation transistors corresponding to the capacitor element connected to the switching means which is turned on is placed in an operating condition.

In the multi-band oscillator, preferably, the emitters of each of the pairs of the oscillation transistors are connected to the corresponding constant-current sources, and the constant-current source connected to the pair of oscillation transistors which are placed in an operating condition are turned on. Therefore, the operating electrical current which is made to flow through the oscillation transistors can be set at an optimum value.

In the multi-band oscillator, preferably, the switching means includes a field-effect transistor, the drain of the field-effect transistor is connected to one of the collectors, and the source thereof is connected to the capacitor element and is grounded via a resistor. Therefore, the capacitor element, which is connected to the field-effect transistor as a result of the field-effect transistor being turned on, can be connected between the collector of one of the oscillation transistors and the collector of the other oscillation transistor.

In the multi-band oscillator, preferably, the higher the oscillation frequency, the larger the electrical current of the corresponding constant-current source is made for a pair of oscillation transistors which are placed in an operating condition. Therefore, the optimum operating electrical current can be made to flow regardless of the oscillation frequency band.

### BRIEF DESCRIPTION OF THE DRAWINGS

FIG. 1 is a circuit diagram showing the configuration of a multi-band oscillator according to the present invention; and

FIG. 2 is a circuit diagram showing the configuration of a conventional multi-band oscillator.

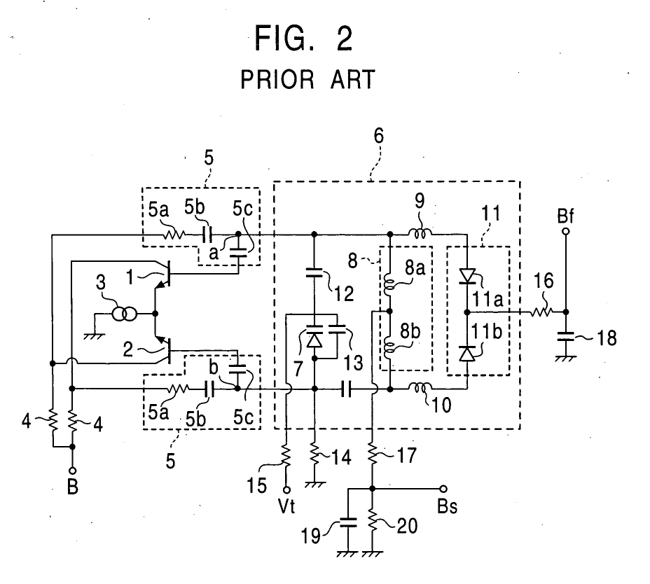

### DESCRIPTION OF THE PREFERRED EMBODIMENT

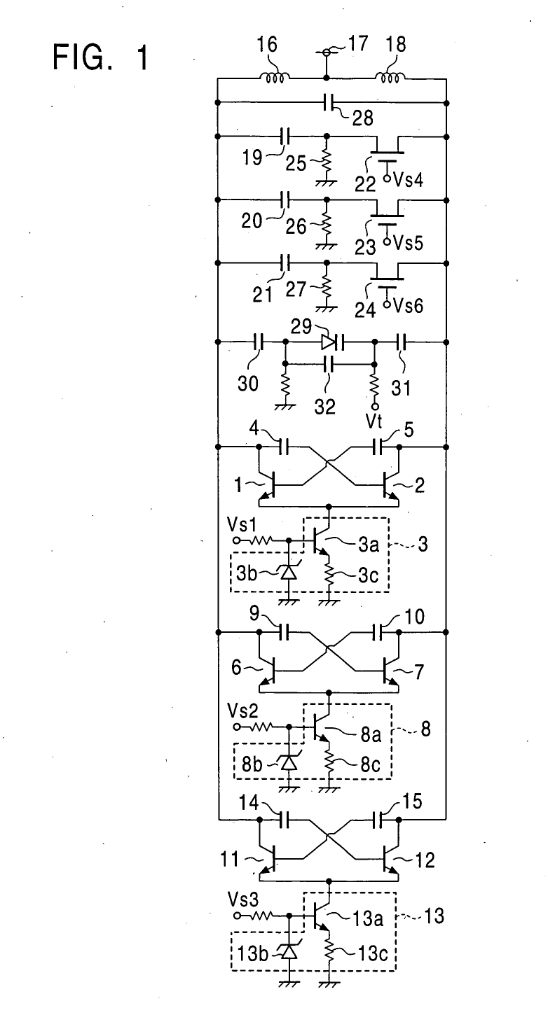

FIG. 1 shows the configuration of a multi-band oscillator according to the present invention. A first pair of oscillation transistors 1 and 2 are differentially connected as a result of their mutual emitters being connected to a first constant-current source 3. Then, the collector of the oscillation transistor 1 and the base of the oscillation transistor 2 are coupled together by a first feedback capacitor element 4, and the base of the oscillation transistor 1 and the collector of the oscillation transistor 2 are coupled together by a second feedback capacitor element 5. The first constant-current source 3 includes a transistor 3a, a zener diode 3b, etc. The collector of the transistor 3a is connected to the emitters of the oscillation transistors 1 and 2, and the emitter of the transistor 3a is grounded via a resistor 3c. The zener diode 3b is connected between the base of the transistor 3a and a ground.

In a similar manner, a second pair of oscillation transistors 6 and 7 are differentially connected as a result of their emitters being connected to a second constant-current source 8. Then, the collector of one of the oscillation transistors 6 and the base of the other oscillation transistor 7 are coupled together by a third feedback capacitor element 9, and the base of one of the oscillation transistors 6 and the collector of the other oscillation transistor 7 are coupled together by a fourth feedback capacitor element 10. The second constant-current source 8 includes a transistor 8a and a zener diode 8b. The collector of the transistor 8a is connected to the emitters of the oscillation transistors 6 and 7, and the emitter of the transistor 8a is grounded via a resistor 8c. The zener diode 8b is connected between the base of the transistor 8a and a ground.

In addition, a third pair of oscillation transistors 11 and 12 are differentially connected as a result of their emitters being connected to a third constant-current source 13. Then, the collector of the transistor 11 and the base of the oscillation transistor 12 are coupled together by a fifth feedback capacitor element 14. The base of the oscillation transistor 11 and the collector of the oscillation transistor 12 are coupled together by a sixth feedback capacitor element 15. The third constant-current source 13 includes a transistor 13a and a zener diode 13b. The collector of the transistor 13a is connected to the emitters of the oscillation transistors 11 and 12, and the emitter of the transistor 13a is grounded via a resistor 13c. The zener diode 13b is connected between the base of the transistor 13a and a ground.

The electrical current values of the three constant-current sources 3, 8, and 13 are set so as to differ from one another by the resistor 3c, 8c, and 13c, respectively. The electrical current value of the first constant-current source 3 is largest, and the electrical current value of the third constant-current source 13 is smallest. Then, the constant-current sources 3, 8, and 13 are turned on by voltages Vs1, Vs2, and Vs3 applied to the bases of the transistors 3a, 8a, and 13a, respectively, causing electrical current to flow.

The collectors of one of each pair of the oscillation transistors 1, 6, and 11, are connected to one another and are connected to a power-supply terminal 17 via an inductance element 16. The collectors of the other oscillation transistors 2, 7, and 12 are connected to one another and are connected to the power-supply terminal 17 via an inductance element 18.

Between the collectors of one of each pair of the oscillation transistors 1, 6, and 11, and the collectors of the other oscillation transistors 2, 7, and 12, three capacitor elements 19, 20, and 21 for switching the oscillation frequency band are connected. The first capacitor element 19 is connected to the source of a field-effect transistor (hereinafter abbreviated as “FET”) 22, which is first switching means, the second capacitor element 20 is connected to the source of an FET 23, which is second switching means, and the third capacitor element 21 is connected to the source of an FET 24, which is third switching means. Then, the sources of the FETs are correspondingly grounded via resistors 25, 26, and 27, and the drains thereof are connected to the collectors of the oscillation transistors 2, 7, and 12. Voltages Vs4, Vs5, Vs6 for turning on the FETs 22, 23, and 24 are applied to the gates thereof, respectively.

The capacitance values of the capacitor elements 19, 20, and 21 are determined by the oscillation frequency band. The first capacitor element 19 is used when the oscillator oscillates at the highest frequency band (for example, 5.8 GHz band), and the capacitance value thereof is smallest. The second capacitor element 20 is used when the oscillator oscillates at an intermediate frequency band (for example, 5.3 GHz band), and the capacitance value thereof is intermediate. The third capacitor element 21 is used when the oscillator oscillates at the lowest frequency band (for example, 4.9 GHz band), and the capacitance value thereof is greatest. Furthermore, the first capacitor element 19 is used together with the first pair of oscillation transistors 1 and 2, the second capacitor element 20 is used together with the second pair of oscillation transistors 6 and 7, and the third capacitor element 21 is used together with the third pair of oscillation transistors 11 and 12.

Furthermore, between the collectors of one of each pair of the oscillation transistors 1, 6, and 11, and the collectors of the other oscillation transistors 2, 7, and 12, a capacitor element 28, which is commonly used at each oscillation band, and a varactor diode 29 for varying the oscillation frequency at each oscillation band are connected. Capacitor elements 30 and 31 for cutting off DC current are connected in series across both ends of the varactor diode 29. Furthermore, a capacitor element 32 for correcting a frequency is connected in parallel to the varactor diode 29. Then, the anode thereof is grounded in DC, and a tuning voltage Vt for varying the oscillation frequency is applied to the cathode thereof.

In the above configuration, in order to cause the oscillator to oscillate at a high frequency band, by turning on the first constant-current source 3 and the FET 22, the first pair of oscillation transistors 1 and 2 are placed in an operating condition, and also, the capacitor element 19 is connected between the collectors thereof. The capacitor element 19, together with the inductance elements 16 and 18 connected in series thereto, the capacitor element 28, and the varactor diode 29, forms a parallel resonance circuit, and this parallel resonance circuit, together with the two oscillation transistors 1 and 2, forms a balanced oscillation circuit.

Similarly, in order to cause the oscillator to oscillate at an intermediate frequency, by turning on the second constant-current source 8 and the FET 23, the second pair of oscillation transistors 6 and 7 are placed in an operating condition, and also, the capacitor element 20 is connected between the collectors thereof. Also, the second capacitor element 20, together with the series-connected inductance elements 16 and 18, the capacitor element 28, and the varactor diode 29, forms a parallel resonance circuit, and this parallel resonance circuit, together with the two oscillation transistors 6 and 7, forms a balanced oscillation circuit.

In addition, in order to cause the oscillator to oscillate at the lowest frequency band, by turning on the third constant-current source 13 and the FET 24, the third pair of oscillation transistors 11 and 12 are placed in an operating condition, and also, the capacitor element 21 is connected between the collectors thereof. Also, the third capacitor element 21, together with the series-connected inductance elements 16 and 18, the capacitor element 28, and the varactor diode 29, forms a parallel resonance circuit, and this parallel resonance circuit, together with the two oscillation transistors 11 and 12, forms a balanced oscillation circuit.

In the present invention, since a pair of oscillation transistors are provided independently for each oscillation frequency band, feedback capacitor elements for coupling together the mutual collectors and bases thereof can be set at a value that matches oscillation conditions. Furthermore, the electrical current which is made to flow through the oscillation transistor can be set independently.

What is claimed is:

1. A multi-band oscillator comprising:
a plurality of pairs of first and second oscillation transistors, which are differentially connected and which are provided independently for each oscillation frequency band; and
a feedback capacitor element that connects the mutual collector and base of each of said pairs of oscillation transistors,
wherein the collectors of the first oscillation transistors are connected to one another,
the collectors of the second oscillation transistors are connected to one another,
a plurality of capacitor elements for switching the oscillation frequency band in such a manner as to correspond to each of said pairs of the oscillation transistor are connected via switching means connected in series thereto between the collectors of said first oscillation transistors and the collectors of said second oscillation transistors, and
only one pair of oscillation transistors corresponding to said capacitor element connected to said switching means which is turned on is placed in an operating condition.

2. A multi-band oscillator according to claim 1, wherein the emitters of each of said pairs of the oscillation transistors are connected to the corresponding constant-current sources, and the constant-current source connected to said pair of oscillation transistors which are placed in an operating condition are turned on.

3. A multi-band oscillator according to claim 1, wherein said switching means comprises a field-effect transistor, the drain of said field-effect transistor is connected to one of said collectors, and the source thereof is connected to said capacitor element and is grounded via a resistor.

4. A multi-band oscillator according to claim 2, wherein the higher the oscillation frequency, the larger the electrical current of the corresponding constant-current source is made for a pair of oscillation transistors which are placed in an operating condition.
